(19) United States
(12) Patent Application Publication
(10) Pub. No.: US 2024/0421239 A1
(43) Pub. Date: Dec. 19, 2024

(54) ULTRA-BROADBAND WAVEGUIDE-COUPLED PHOTODETECTOR ON THIN-FILM LITHIUM NIOBATE PLATFORM

(71) Applicant: Southwest Jiaotong University, Chengdu (CN)

(72) Inventors: Xiaojun Xie, Chengdu (CN); Chao Wei, Chengdu (CN); Xihua Zou, Chengdu (CN); Wei Pan, Chengdu (CN); Lianshan Yan, Chengdu (CN)

(21) Appl. No.: 18/743,136

(22) Filed: Jun. 14, 2024

(30) Foreign Application Priority Data
Jun. 16, 2023 (CN) 202310715536.0

(51) Int. Cl. H01L 31/0304; H01L 31/0232; H01L 31/18

(52) U.S. Cl. CPC H01L 31/03046; H01L 31/02327; H01L 31/1844

(57) ABSTRACT

An ultra-broadband waveguide-coupled photodetector on a TFLN platform is provided. Specifically, the waveguide-coupled photodetector on a TFLN-InP heterogeneous integration platform is prepared. An epitaxial layer is grown on a semi-insulating InP substrate by metal-organic chemical vapor deposition, and the epitaxial layer includes a n-contact layer, a sacrificial layer, a drift layer, a cliff layer, a quaternary compound layer, an absorption layer and a p-contact layer sequentially arranged in that order. The n-contact layer and the p-contact layer are heavily doped with InGaAs and InGaAsP, respectively. The absorption layer includes a depletion absorption layer with a thickness of 20 nm and a graded doping absorption layer with a thickness of 100 nm. The photodetector simultaneously improves bandwidth and responsivity, and can be compatible with mature silicon processes and applied to four-level pulse amplitude modulation data receiving systems.

### TECHNICAL FIELD

The disclosure relates to the technical field of photoelectric detection, and more particularly to an ultra-broadband waveguide-coupled photodetector (PD) on a thin-film lithium niobate (TFLN) platform.

### BACKGROUND

Integrated photonics holds great prospects for achieving low-cost and large-scale implementation in fields such as communication, sensing, and computing. A variety of material systems have been studied and applied in integrated photonics, such as silicon, indium phosphide (InP), silicon nitride (SiNₓ), gallium arsenide (GaAs), aluminum nitride (AlN), and silicon carbide (SiC). Despite significant achievements, these material platforms cannot simultaneously support ultra-low transmission loss, fast low-loss optical modulation, and efficient all-optical nonlinearity. Lithium niobate (LiNbO₃, LN) has become one of the universal and highly attractive materials in integrated photonics due to its unique acousto-optic, electro-optic, and nonlinear effects, as well as its wide transparency window. Traditional bulk lithium niobate devices have been limited in their application due to weak mode confinement, large device footprint, and low nonlinear efficiency. The advent of TFLN technology has achieved high optical confinement and significant optical nonlinear efficiency, which has had a significant impact in a wide range of applications such as optical communication, microwave photonics, terahertz communication, and quantum photonics.

In the past few years, with the commercialization of high-quality TFLN wafers and breakthroughs in manufacturing technology, the TFLN wafers have been used to develop multifunctional optoelectronic components. Nearly a complete set of integrated optical components, such as nanophotonic LN waveguides with ultra-low loss, high refractive index contrast, compact and ultra-high-performance modulators, broadband frequency comb sources and efficient wavelength converters, have been fabricated, which has unprecedented performance. However, due to the inherent difficulty of realizing light sources and detection with lithium niobate material itself, the aforementioned TFLN devices have been demonstrated using external lasers and PDs, which represents the main challenge for the TFLN integrated photonics platform. Recently, the flip-chip bonding technique has been utilized to integrate an InP distributed feedback (DFB) laser with a prefabricated TFLN modulator chip: 1) A. Shams-Ansari, D. Renaud, R. Cheng, L. Shao, L. He, D. Zhu, M. Yu, H. R. Grant, L. Johansson, M. Zhang, and M. Loncar, “Electrically pumped laser transmitter integrated on thin-film lithium niobate,” Optica 9, 408-411 (2022). A low-loss and high-power TFLN-InP transmitter has been realized by optimizing the overlap between the platform modes. In addition, broadband optical detection has demonstrated for the first time on the TFLN platform using SU8 as the bonding layer: 2) X. Guo, L. Shao, L. He, K. Luke, J. Morgan, K. Sun, J. Gao, T. C. Tzu, Y. Shen, D. Chen, B. Guo, F. Yu, Q. Yu, M. Jafari, M. Loncar, M. Zhang, and A. Beling, “High-performance modified uni-traveling carrier photodiode integrated on a thin-film lithium niobate platform,” Photonics Res. 10, 1338 (2022). By heterogeneously integrating InP/indium gallium arsenide (InGaAs) epitaxial chips on the TFLN wafers, high-performance PDs have been realized, featuring a 3-decibel (dB) bandwidth of 80 gigahertz (GHz) and a responsivity of 0.6 ampere per watt (A/W) at 1550 nanometers (nm). Considering that the state-of-the-art TFLN modulators have a bandwidth of 110 GHz, there is still a significant need for ultra-broadband PDs to be implemented on the TFLN platform.

### SUMMARY

To solve the above problems, an ultra-broadband waveguide-coupled photodetector on a thin-film lithium niobate (TFLN) platform is provided.

In an aspect of the disclosure, the epitaxial layer is deposited on an indium phosphide (InP) substrate by metal-organic chemical vapor deposition (MOCVD). The epitaxial layer includes a n-contact layer, a sacrificial layer, a drift layer, a cliff layer, a quaternary compound layer, an absorption layer and a p-contact layer arranged sequentially in that order. The heterogeneous integrated waveguide-coupled photodetector on a TFLN chip is prepared by bonding the InP substrate with the TFLN chip, after the bonding, a structure of a p-type region at a bottom of the structure and a n-type region at the top of the structure is formed.

The n-contact layer and the p-contact layer are heavily doped with indium gallium arsenide (InGaAs) and indium gallium arsenide phosphide (InGaAsP), respectively.

The absorption layer includes a depletion absorption layer with a thickness of 20 nanometers (nm) and a graded doping absorption layer with a thickness of 100 nm.

The photodetector has a dark current of 1 nanoampere (nA) and a responsivity of 0.4 amperes per watt (A/W) at a wavelength of 1550 nm to achieve a bandwidth of 110 gigahertz (GHz) under a load of 50 ohms (Ω).

In another aspect, a preparation method of the ultra-broadband waveguide-coupled photodetector on the TFLN platform is further provided and includes steps as follows: thinning the InP substrate to expose the n-contact layer, etching the thinned InP substrate and stop etching when the p-contact layer is exposed by using a combination of a dry etching and a wet etching, thereby forming a n-mesa; after forming the n-mesa, etching to the lithium niobate (LN) layer of the TFLN chip through the combination of the dry etching and the wet etching, thereby forming a p-mesa; and forming metal electrodes on the n-mesa and the p-mesa respectively through electroplating, so as to obtain the ultra-broadband waveguide-coupled photodetector.

The benefits of the disclosure are as follows.

1. The p-down structure of the ultra-broadband waveguide-coupled photodetector simultaneously improves its bandwidth and responsivity.

2. The TFLN in the disclosure is a silicon-based thin-film lithium niobate, which can be compatible with mature silicon process.

3. The photodetector of the disclosure have been successfully applied to a four-level pulse amplitude modulation (PAM4) data reception system, demonstrating the great potential of the photodetector in high-speed optical link systems on the TFLN platform.

### BRIEF DESCRIPTION OF DRAWINGS

FIG. 1 illustrates data of a structure of an epitaxial layer of a photodetector of the disclosure.

FIG. 2 illustrates an optical microscope image of the photodetector of the disclosure.

FIG. 3 illustrates a scanning electron microscopy image of the photodetector of the disclosure.

FIG. 4 illustrates a dark current diagram of the photodetector at different active areas of the disclosure.

FIG. 5A illustrates a frequency response diagram of the photodetector at an active area with 2 micrometers (μm)×6 μm of the disclosure.

FIG. 5B illustrates a frequency response diagram of the photodetector at an active area with 2 μm×8 μm of the disclosure.

FIG. 5C illustrates a frequency response diagram of the photodetector at an active area with 2 μm×10 μm of the disclosure.

FIG. 5D illustrates a frequency response diagram of the photodetector at an active area with 2 μm×12 μm of the disclosure.

FIG. 5E illustrates a frequency response diagram of the photodetector at an active area with 2 μm×14 μm of the disclosure.

FIG. 6 illustrates a relationship between a bit error rate (BER) and an optical power of the prepared photodetector receiving a signal of 32 Gbaud PAM4.

FIG. 7 illustrates a summary of a bandwidth and a responsivity of III-V photodiodes heterogeneously integrated on non-native substrates.

### DETAILED DESCRIPTION OF EMBODIMENTS

A further detailed explanation of the disclosure will be provided below and in conjunction with the attached drawings and specific implementation methods.

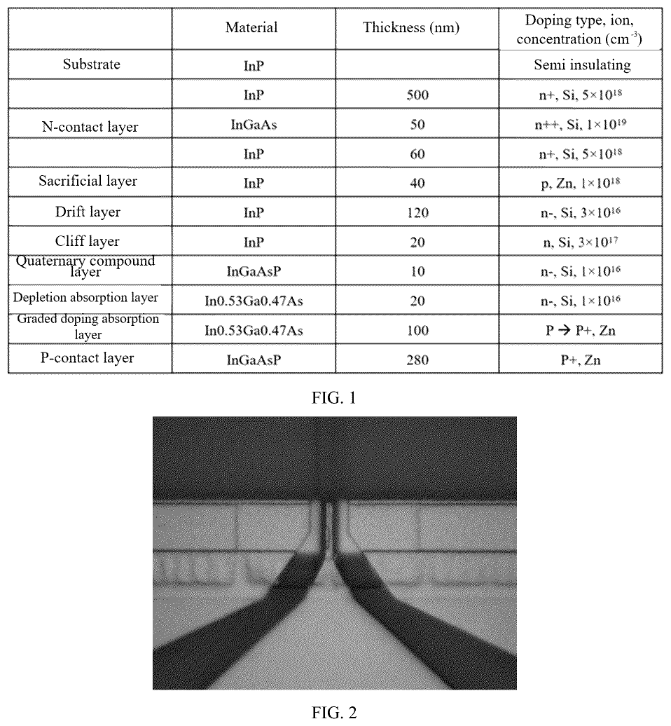

An ultra-broadband waveguide-coupled photodetector on a thin-film lithium niobate (TFLN) platform, which involves growing an epitaxial layer on a semi-insulating indium phosphide (InP) substrate by metal-organic chemical vapor deposition (MOCVD). A structure on the epitaxial layer is as shown in FIG. 1 and includes a n-contact layer, a sacrificial layer, a drift layer, a cliff layer, a quaternary compound layer, an absorption layer and a p-contact layer sequentially arranged in that order. The waveguide-coupled photodetector heterogeneously integrated on a TFLN chip is prepared by bonding a InP wafer with the TFLN chip, in which a p-type region is disposed below a n-type region.

To achieve electron velocity overshoot, the electric field in the drift region (i.e., the drift layer) is adjusted to a suitable value by the p-type doped sacrificial layer. The n-contact layer and the p-contact layer are heavily doped with indium gallium arsenide (InGaAs) and indium gallium arsenide phosphide (InGaAsP), respectively. The p-contact layer heavily doped with InGaAsP layer also serves as a light coupling layer, thereby enabling efficient optical coupling between the active layer and the lithium niobate (LN) waveguide.

The absorption layer includes a depletion absorption layer with a thickness of 20 nanometers (nm) and a graded doping absorption layer with a thickness of 100 nm. Due to efficient light coupling, the absorption layer with the thickness of 120 nm can achieve effective light absorption.

The photodetector has a dark current of 1 nanoampere (nA) and a responsivity of 0.4 ampere per watt (A/W) at a wavelength of 1550 nm, and the measured 3-decibel (dB) bandwidth is up to 110 gigahertz (GHz) under a load of 50 ohms (Ω).

A preparation method of the ultra-broadband waveguide-coupled photodetector on the TFLN platform is provided as follows.

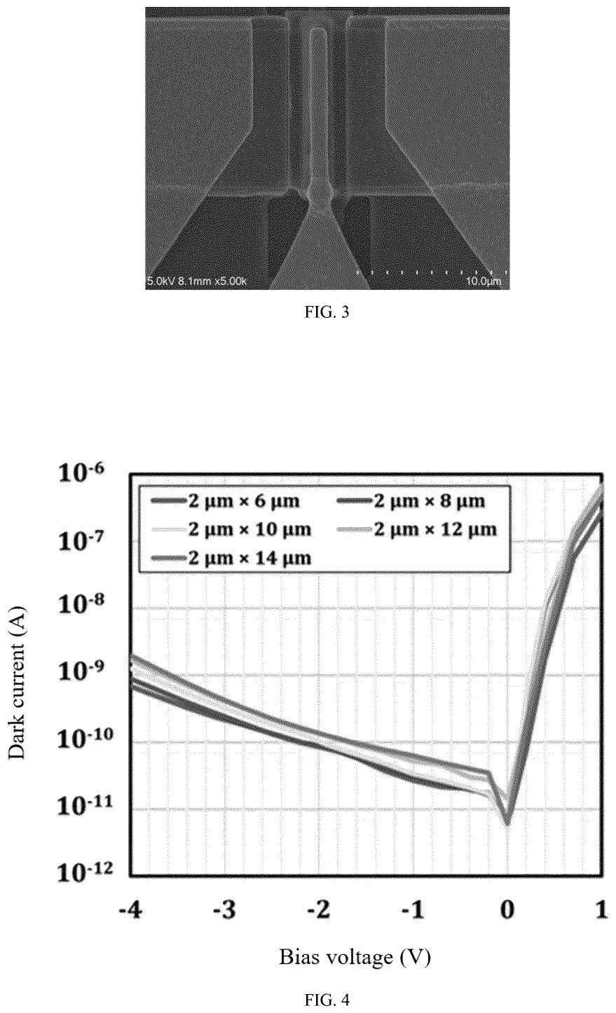

First, the InP wafer is bonded to a TFLN wafer with waveguides and passive optical components. The InP substrate deposited with the epitaxial layer is thinned to expose the n-contact layer, the thinned InP substrate is etched by using a combination of a dry etching and a wet etching and the etching is stopped when the p-contact layer is exposed, thereby forming a n-mesa. This step defines the sizes of the photodetectors' active areas, which ranges from 2 μm×6 μm to 2 μm×14 μm. The etched InP substrate is etched after the n-mesa is formed by using the combination of the dry etching and the wet etching and the etching is stopped when lithium niobate (LN) of the TFLN chip is exposed, thereby forming a p-mesa. Metal electrodes are formed on the n-mesa and the p-mesa respectively through electroplating, so as to obtain the ultra-broadband waveguide-coupled photodetector. The wafer is cut into pieces, and followed by polishing on sides of the pieces. An optical microscope image of the ultra-broadband waveguide-coupled photodetector on the TFLN is shown in FIG. 2, and a scanning electron microscopy image of the photodetector is shown in FIG. 3.

### Photodetector Testing

First, the dark currents of the photodetectors are tested. FIG. 4 shows relationships between the dark currents and the bias voltage of the photodetectors with active areas ranging from 2 μm×6 μm to 2 μm×14 μm. The typical dark current of the photodetector at a −4 voltages (V) bias is about 1 nA. Secondly, to measure the internal responsivity of the photodetector, it is necessary to characterize the coupling loss from the fiber to the waveguide and the waveguide loss. A lensed fiber with a spot size of 2.5 μm is used to couple light into the exposed ring waveguides near the target photodetector. The responsivity is calculated by measuring the photocurrent in the photodetector of the same chip to which the light is coupled. The coupling loss and waveguide propagation loss are approximately 7 dB. At a wavelength of 1550 nm, taking into account the coupling loss and waveguide propagation loss, the measured responsivities for photodetectors with lengths of 6 μm to 14 μm are 0.4, 0.48, 0.5, 0.54, and 0.55 A/W, respectively. The actual measured responsivities of the photodetectors are essentially consistent with the simulated responsivity rate.

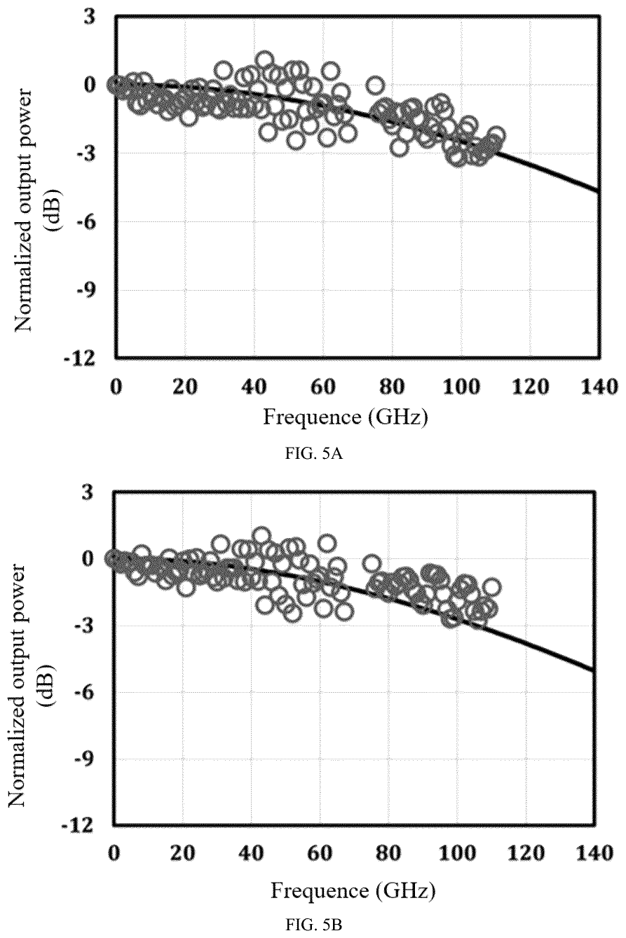

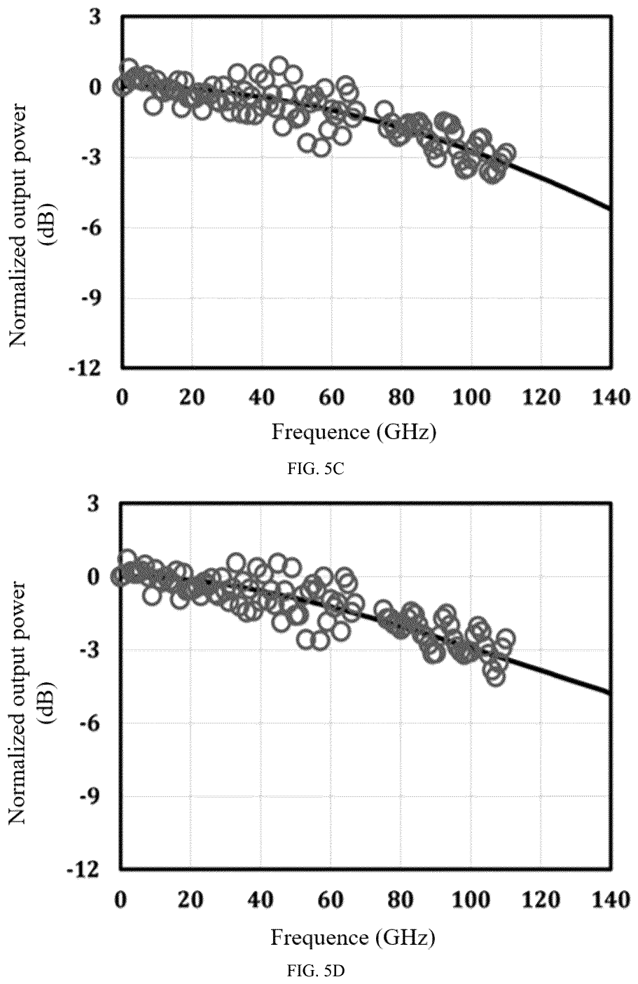

The bandwidth of the photodetector is tested using the heterodyne method to generate an optical beat signal. FIGS. 5A-5E illustrate the frequency response diagrams of photodetectors with different active area sizes. The solid lines represent the frequency response calculated from the parameters of the photodetectors extracted using S-parameters, and the circles represent the actual test results. It can be observed that the test results are matched with the simulation results in each FIG. The photodetectors with active areas of 2 μm×6 μm, 2 μm×8 μm, 2 μm×10 μm, 2 μm×12 μm, and 2 μm×14 μm have maximum bandwidths of 110 GHz, 105 GHz, 100 GHz, 101 GHz, and 97 GHz, respectively.

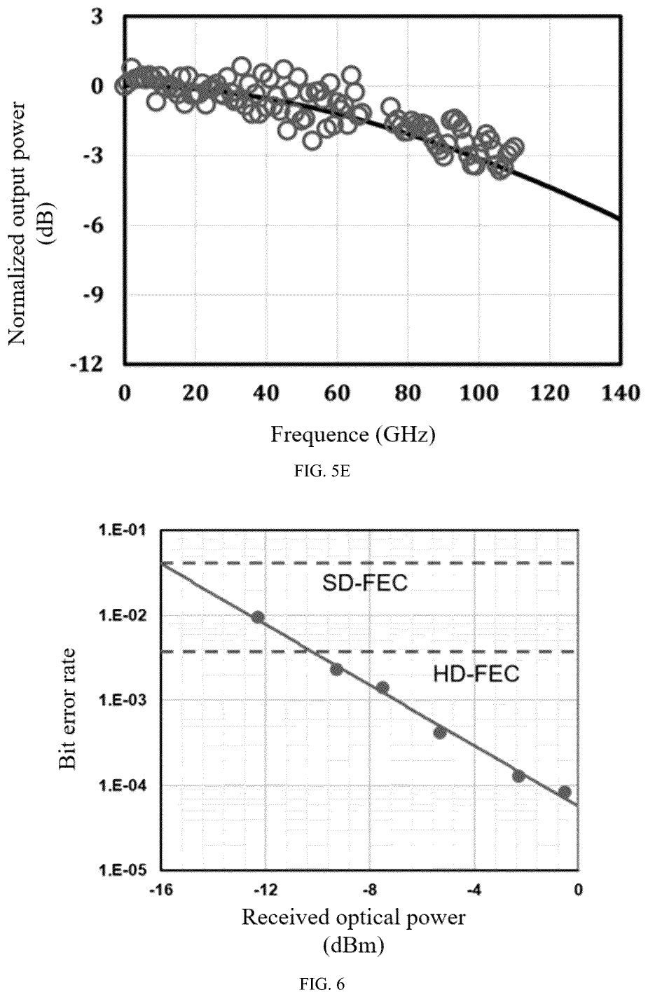

Finally, to further verify the performance of the photodetector, the photodetector is applied to a four-level pulse amplitude modulation (PAM4) data reception system. In the experiment, an arbitrary waveform generator is used to produce PAM4 signals at rates of 10 Gbaud, 20 Gbaud, and 32 Gbaud. A transmission signal with 131072 data cycles is used to achieve error-free transmission at 10 Gbaud, 20 Gbaud, and 32 Gbaud. Additionally, the relationship between the bit error rate and optical power for the 32 Gbaud PAM4 signal is studied, as shown in FIG. 6. The results indicate that when the signal optical power exceeds −16 dBm, the bit error rate remains below the soft decision forward error correction (SD-FEC) threshold of 4×10⁻². Furthermore, when the power exceeds −10 dBm, the bit error rate is below the hard decision forward error correction (HD-FEC) threshold of 3.8×10⁻³.

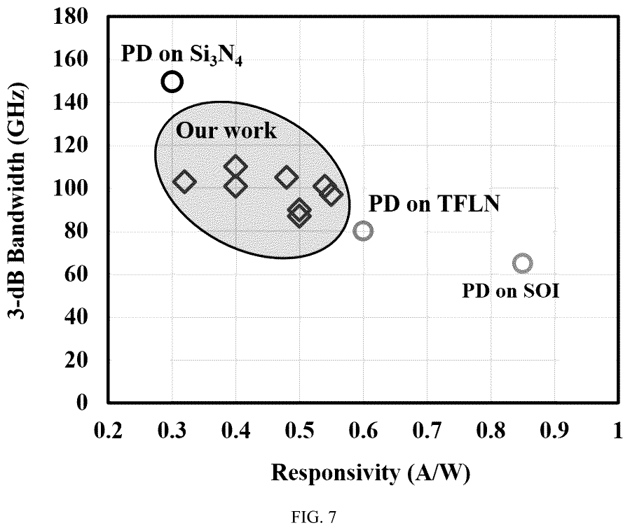

FIG. 7 illustrates a summary of a bandwidth and a responsivity of III-V photodiodes heterogeneously integrated on non-native substrates that have been reported to date. The TFLN PDS achieve both high bandwidth and responsivity.

What is claimed is:

1. An ultra-broadband waveguide-coupled photodetector on a thin-film lithium niobate (TFLN) platform, comprising:
an epitaxial layer, grown on an indium phosphide (InP) substrate by metal-organic chemical vapor deposition (MOCVD), and comprising: a n-contact layer, a sacrificial layer, a drift layer, a cliff layer, a quaternary compound layer, an absorption layer and a p-contact layer arranged sequentially in that order;
wherein the waveguide-coupled photodetector heterogeneously integrated on a TFLN chip is prepared by bonding the InP substrate with the TFLN chip, and a p-type region is disposed below a n-type region in the waveguide-coupled photodetector;
wherein the n-contact layer and the p-contact layer are doped with indium gallium arsenide (InGaAs) and indium gallium arsenide phosphide (InGaAsP), respectively; and
wherein the absorption layer comprises a depletion absorption layer with a thickness of 20 nanometers (nm) and a graded doping absorption layer with a thickness of 100 nm.

2. The ultra-broadband waveguide-coupled photodetector on the TFLN platform as claimed in claim 1, wherein the photodetector has a dark current of 1 nanoampere (nA) and a responsivity of 0.4 amperes per watt (A/W) at a wavelength of 1550 nm to achieve a bandwidth of 110 gigahertz (GHz) under a load of 50 ohms (Ω).

3. A preparation method of the ultra-broadband waveguide-coupled photodetector on the TFLN platform as claimed in claim 1, comprising:
thinning the InP substrate to expose the n-contact layer, etching the thinned InP substrate and stop etching when the p-contact layer is exposed by using a combination of a dry etching and a wet etching, thereby forming a n-mesa;
after forming the n-mesa, etching to a lithium niobate (LN) layer of the TFLN chip through the combination of the dry etching and the wet etching, thereby forming a p-mesa; and
forming metal electrodes on the n-mesa and the p-mesa respectively through electroplating, so as to obtain the ultra-broadband waveguide-coupled photodetector.
